(19) United States
(12) Patent Application Publication
(10) Pub. No.: US 2003/0227030 A1
(43) Pub. Date: Dec. 11, 2003

(54) Light emitting semiconductor device

(76) Inventors: Masaki Tatsumi, Tenri-shi (JP); Masahiro Konishi, Ikoma-shi (JP); Toshio Hata, Mihara-shi (JP); Mayuko Fudeta, Mihara-shi (JP)

Correspondence Address: Thomas E. Ciotti, Morrison & Foerster LLP, 755 Page Mill Road, Palo Alto, CA, 94304-1018, US

(21) Appl. No.: 10/388,980

(22) Filed: Mar. 14, 2003

(30) Foreign Application Priority Data
Mar. 15, 2002 (JP) 2002-071348

(51) Int. Cl. H01L 31/0328

(52) U.S. Cl. 257/200

(57) ABSTRACT

Disclosed is a light emitting semiconductor device which contains LED chip(s) wherein semiconductor layer(s) comprising P—N junction(s) is or are laminated over substrate(s) and which is equipped with support structure(s) providing electrical continuity to such LED chip(s), such LED chip(s) being covered by resin. Such LED chip(s) is or are secured by way of intervening first resin(s) to mounting surface(s) of the support structure(s) and is or are covered by second resin(s). First resins(s) and second resin(s) are the same resin(s).

### BACKGROUND OF INVENTION

1. Field of Invention

The present invention relates to a light emitting device employing semiconductor(s) comprising nitride-type compound(s).

2. Conventional Art

Green, blue, white, and other such visible-region LED lamps, and also LED lamps operating in short-wavelength regions such as the ultraviolet, have been commercialized, such LED lamps being equipped with light emitting elements in the form of LED chips employing GaN, AlGaN, InGaN, and other such semiconductors comprising nitride-type compounds. Because such semiconductor materials comprising nitride-type compounds possess excellent luminous efficiency, the LED lamps which have been developed include some which have high luminance.

With such LED lamps, the LED chip is first secured to a lead frame using Ag paste, and this is then sealed using epoxy resin. Whereas one factor in LED lamp reliability is the reliability of the LED chip itself, the weather resistance of this epoxy resin affects LED lamp reliability. For example, aromatic carbon—carbon double bonds present within epoxy resin may be broken down due to heat and/or irradiation by short-wavelength visible and/or ultraviolet light, causing oxidation and yellowing, and leading to decreased optical transmissivity. In particular, with LED chips such as the foregoing which employ semiconductors comprising nitride-type compounds, the light emitted is of high energy, and there is also much generation of heat due to the high operating voltages of 3 V to 5 V. There is therefore concern because of the large possibility that LED lamp reliability could be impaired due to oxidative degradation of the molded resin.

In order to address such concerns in more practical fashion, the present applicant carried out reliability testing of LED lamps possessing conventional structures. The LED lamp employed for this testing was such that a blue LED chip (peak emission wavelength=470 nm) wherein a multilayer semiconductor film comprising a nitride-type compound and having a P—N junction, a p-type electrode, and an n-type electrode were formed over sapphire substrate, a protective layer being formed at prescribed locations over the electrodes, was mounted with Ag paste onto a lead frame cup, epoxy resin being used during molding to produce an LED lamp that was 5 φ in size (15 mm in diameter).

Reliability testing was carried out with respect to low-temperature operation, high-temperature high-humidity operation, low-temperature storage, and high-temperature high-humidity storage, 100 samples being employed for each. Conditions for the various tests were as indicated in TABLE 1, below.

TABLE 1

| | Ambient | | | |
|---|---|---|---|---|
| | Conditions | | Relative | Relative |
| | (Temperature/ | Electricity | Operating | Emitted |
| Test | Humidity) | Supplied | Voltage | Luminance |
| Low- | −40° C. | 30 mA | 95%-98% | 125%-130% |
| Temperature | | | | |
| Operation | | | | |
| High- | 60° C./90% | 20 mA | 95%-98% | 60%-70% |
| Temperature | | | | |
| High-Humidity | | | | |
| Operation | | | | |
| Low- | −40° C. | None | 95%-98% | 98%-100% |
| Temperature | | | | |
| Storage | | | | |
| High- | 60° C./90% | None | 95%-98% | 98%-100% |
| Temperature | | | | |
| High-Humidity | | | | |
| Storage | | | | |

Electricity supplied and ambient conditions (temperature/humidity) in the various tests described below are as indicated here.

Relative operating voltage and relative emitted luminance are defined as percents of values measured for operating voltage and emitted luminance prior to the start of testing at a time when 20 mA of electricity was supplied at room temperature, TABLE 1 showing, for each test, relative operating voltage and relative emitted luminance after undergoing testing for 2,000 hours.

Relative operating voltage was, for all tests, almost completely unchanged from initial values, being 95% to 98% of the initial value after 2,000 hours. Relative emitted luminance exhibited a trend toward improving over the course of the low-temperature operation test, and exhibited a trend toward deteriorating over the course of the high-temperature high-humidity operation test. Particularly for the high-temperature high-humidity operation test, emitted luminance was 60% to 70% of initial values, this representing a large deteriorating trend. There was almost no change over the course of the low-temperature storage test and the high-temperature high-humidity storage test.

It is clear from the foregoing test results that the way in which emitted luminance changes varied depending on the ambient conditions (temperature/humidity) and on whether or how much electricity was supplied during testing. Whereas there was actually a trend toward improvement at low temperature, deterioration was particularly marked with supply of electricity at high temperature.

Upon investigating the causes behind the foregoing results, it was learned that the problem was not due so much to deterioration of the characteristics of the LED chip itself or degradation of the molded resin itself as it was to alteration in the closeness of contact between the molded resin and the LED chip. That is, the LED chip is in physical contact with two materials having different coefficients of thermal expansion: the epoxy resin which constitutes the resin used for molding, and the Ag paste which is used to mount it to the lead frame. There are therefore regions surrounding the LED chip which differ with respect to the closeness with which they make contact, causing occurrence of a stress distribution around the LED chip, and ultimately leading to separation of the chip. It was in particular learned that the change in closeness of contact between the LED chip and the resin used for molding was connected with temperature-related variation in stresses present throughout the resin used for molding which act on the LED chip.

### SUMMARY OF INVENTION

The present invention was conceived in light of the foregoing problem, it being an object thereof to provide a light emitting semiconductor device which exhibits little change in luminance over time, without being affected by ambient temperature and/or operating conditions.

In order to achieve the foregoing object, in the context of a light emitting semiconductor device equipped with one or more LED chips in which one or more semiconductor layers comprising one or more P—N junctions are laminated over one or more substrates, and one or more support structures, on which at least one of the LED chip or chips is mounted and which provide electrical continuity to at least one of the LED chip or chips, at least one of the LED chip or chips being covered with resin, a light emitting semiconductor device in accordance with the present invention is characterized in that at least one of the LED chip or chips is secured by way of one or more intervening first resins to one or more mounting surfaces of at least one of the support structure or structures, and is covered by one or more second resins.

It is preferred that at least one thickness of at least one of the first resin or resins be not less than 5μ and not more than 10μ.

In the context of a light emitting semiconductor device equipped with one or more LED chips in which one or more semiconductor layers comprising one or more P—N junctions are laminated over one or more substrates, and one or more support structures, on which at least one of the LED chip or chips is mounted and which provide electrical continuity to at least one of the LED chip or chips, at least one of the LED chip or chips being covered with resin, another light emitting semiconductor device in accordance with the present invention is characterized in that at least one cavity, the perimeter at the top face of which is larger than the outer periphery of the back face of the at least one LED chip, is provided at one or more mounting surfaces of at least one of the support structure or structures; the at least one cavity is filled with one or more first resins in cured state or states; the at least one LED chip is secured over at least one of the first resin or resins by way of one or more intervening thermally conductive chip adhesives, at least one of the chip adhesive or adhesives being in physical contact with at least one of the mounting surface or surfaces; and the at least one LED chip is covered by one or more second resins.

In the foregoing structure(s), at least one of the first resin or resins and at least one of the second resin or resins may be the same resin.

With a light emitting semiconductor device constituted as described above, because resin(s) having coefficient(s) of thermal expansion on the same order are present around LED chip(s), stresses acting on LED chip(s) from resin(s) are made uniform around LED chip(s). There is accordingly little variation in the closeness with which resin(s) contacts or contact LED chip(s), reducing likelihood that resin(s) will separate from LED chip(s). As a result, there is reduced likelihood of change in the efficiency with which light from the LED chip is extracted to the exterior, and variation in emitted luminance can be kept to a minimum.

Furthermore, it is preferred that chip adhesive(s) has or have thermal conductivity of not less than 2.5 W/m/K.

Moreover, it is preferred that the foregoing chip adhesive(s) possesses or possess electrical conductivity such that the volume resistivity thereof is not more than 600 nΩm.

Because the foregoing chip adhesive(s) will exhibit almost no thermal expansion or contraction, it or they will contribute nothing toward the stresses on the LED chip.

### BRIEF DESCRIPTION OF DRAWINGS

FIG. 1 is a sectional view of a light emitting semiconductor device in accordance with a first embodiment of the present invention.

FIG. 2 is a sectional view of a light emitting semiconductor device in accordance with a second embodiment of the present invention.

FIG. 3 is a sectional view of a light emitting semiconductor device in accordance with a third embodiment of the present invention.

FIG. 4(a) and (b) are sectional views of light emitting semiconductor devices in accordance with other embodiments of the present invention.

FIG. 5(a) and (b) are sectional views of light emitting semiconductor devices in accordance with different embodiments of the present invention.

### DESCRIPTION OF PREFERRED EMBODIMENTS

Below, embodiments of the present invention are described with reference to the drawings.

<First Embodiment>

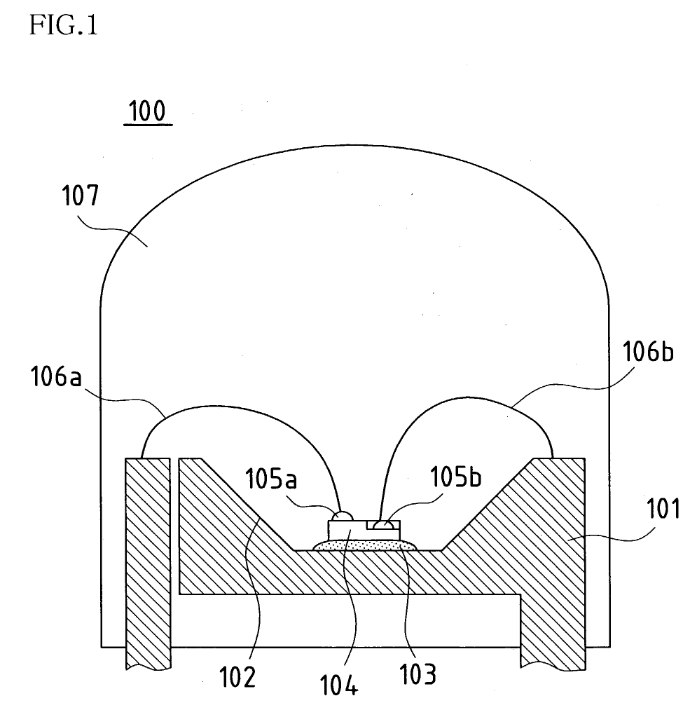

FIG. 1 is a sectional view of an LED lamp in accordance with a first embodiment of the present invention. As light emitting element, this LED lamp 100 has an LED chip 104 wherein multilayer semiconductor film containing a nitride-type compound and comprising a P—N junction is formed over sapphire substrate. Below, a procedure for assembling LED lamp 100 is described.

A dispenser is used to apply a prescribed amount of first resin 103 to cup 102 of lead frame 101 which is secured to a die bonder (not shown), and LED chip 104 is placed on top of this first resin 103. With the assembly in this state, first resin 103 is cured by heating in accordance with prescribed conditions.

p-Pad electrode 105a and n-pad electrode 105b are then formed at the principal plane of LED chip 104, electrical connection between respective electrodes 105a and 105b and lead frame 101 being accomplished by means of wires 106a and 106b. Molding is then carried out using second resin 107. The same resin was used for first resin 103 and second resin 107, an epoxy resin (Ablestik Product No. 2017M) being used in the present embodiment. There is no limitation with respect to this or these resin(s), provided only that it or they is or are consistent with the intent of the present invention.

If the coefficients of thermal expansion of first resin 103 and second resin 107 are very different, differences in coefficient of thermal expansion, adhesive strength, and/or hardness during supply of electricity and/or changes in ambient temperature will cause balances affecting relaxation of internal stresses arising in connection with resin expansion and contraction to be disturbed, causing changes in the closeness of contact between LED chip 104 and resins 103 and 107 as well as concomitant changes in the efficiency with which light is extracted to the exterior, and making emitted luminance extremely likely to exhibit variation. Furthermore, in a worst-case scenario, separation at interface(s) where contact is made with first resin 103 and second resin 107 could serve as trigger, inducing separation of resin from LED chip 104, and moreover, potentially serving as cause for cracking of resin and/or breaking of wires as the assembly attempts to relax the internal stresses which would be produced in the resin(s) in accompaniment to such separation.

Furthermore, thermal conductivity of resin being typically in the neighborhood of one order of magnitude smaller than that of Ag paste, since dissipation of heat in the present embodiment described above will be worse than would be the case had LED chip 104 been secured to the cup using Ag paste, and since this could lead to decreased reliability, it is preferred that the thermal resistance of the first resin be lowered by making the thickness of the first resin somewhat small. In addition, because making this thickness too small would interfere with ability to preserve the balance in the stresses from the resin which act on LED chip 104, it is necessary that this thickness be made somewhat large. Establishing an appropriate value for this resin thickness is important for maintaining high reliability. Now, based on experiments carried out by the present applicant, a thickness of not less than 5μ and not more than 10μ is optimal for the first resin. Where LED chip 104 employs a structure formed over an insulating substrate, such a value represents a preferred value for the thickness of the first resin which is used to secure it to the cup of lead frame 101.

100 samples were employed for each a low-temperature operation test and a high-temperature high-humidity operation test, and relative emitted luminance characteristics over time were measured up to 2,000 hours. TABLE 2, below, shows relative emitted luminance after 100 hours, 500 hours, 1,000 hours, and 2,000 hours. As a comparative example, results are also shown for a structure similar to that of the present embodiment in all respects except for the fact that the LED chip was secured to the cup using Ag paste. In the low-temperature, operation test carried out on the first embodiment, relative emitted luminance after 100 hours had improved relative to the value at the start of testing, being 110% to 115% thereof, and this value was thereafter maintained in stable fashion, such state remaining unchanged throughout measurements made up to 2,000 hours.

TABLE 2

| | Low-Temperature | | High-Temperature High- | |
|---|---|---|---|---|
| Elapsed | Operation Test | | Humidity Operation Test | |
| Time | First | Comparative | | Comparative |
| (hours) | Embodiment | Example | First Embodiment | Example |
| 100 | 110%-115% | 125%-130% | 95%-98% | 90%-95% |
| 500 | 110%-115% | 125%-130% | 92%-95% | 85%-90% |
| 1,000 | 110%-115% | 125%-130% | 85%-90% | 70%-80% |
| 2,000 | 110%-115% | 125%-130% | 80%-85% | 60%-70% |

On the other hand, in the high-temperature high-humidity operation test, while there was a steady decrease in emitted luminance, even after 2,000 hours the relative emitted luminance obtained was 80% to 85%. At the comparative example, while there was the same trend of changing emitted luminance over time as at the first embodiment, relative emitted luminance after 2,000 hours was 125% to 130% in the low-temperature operation test but had dropped to 60% to 70% in the high-temperature high-humidity operation test, the deterioration in emitted luminance over time being more gradual for the LED lamp of the first embodiment than for that of the comparative example. Furthermore, with respect to the change represented by the trend toward increased emitted luminance during the low-temperature operation, since—e.g., where a full-color display is being manufactured or the like—this could disturb balance in luminescence or brightness of other colors, excessive increase thereof would not necessarily be a good thing.

<Second Embodiment>

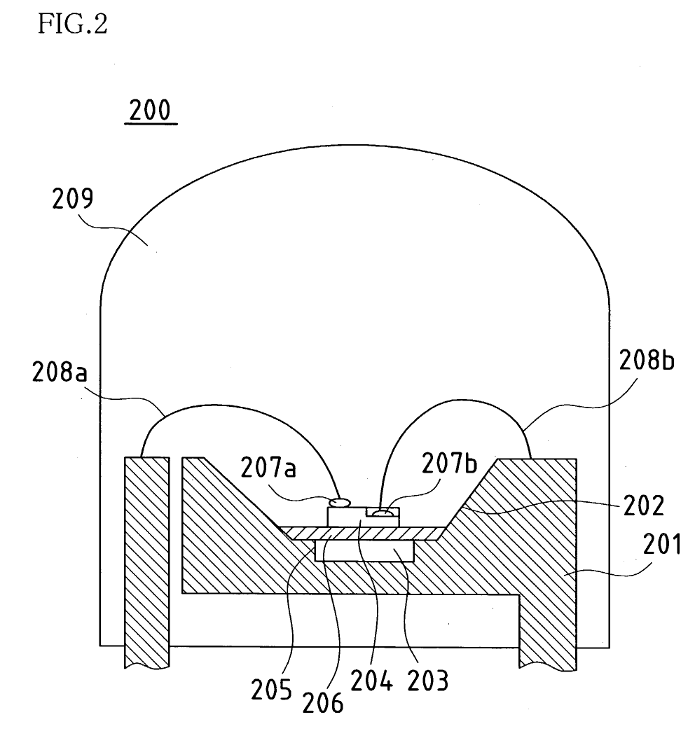

FIG. 2 is a sectional view of an LED lamp in accordance with a second embodiment of the present invention. As light emitting element, this LED lamp 200 has an LED chip 204 wherein multilayer semiconductor film containing a nitride-type compound and comprising a P—N junction is formed over sapphire substrate. Below, a procedure for assembling LED lamp 200 is described.

A dispenser is used to apply a prescribed amount of first resin 203 to cup 202 of lead frame 201 which is secured to a die bonder (not shown). Formed in the center at the bottom of cup 202 is a cavity 205 which is slightly larger than the outer periphery of LED chip 204, first resin 203 being applied so as to fill the region at the interior of this cavity 205. The surface of this first resin 203 is made smooth, and first resin 203 is heated and cured before proceeding. In addition, chip adhesive 206, to which filler has been added, is applied to the cured first resin 203 and to the bottom of cup 202, LED chip 204 is placed over the applied chip adhesive 206, and this is heated and cured.

p-Pad electrode 207a and n-pad electrode 207b are then formed at the principal plane of LED chip 204, electrical connection between respective electrodes 207a and 207b and lead frame 201 being accomplished by means of wires 208a and 208b. Molding is then carried out using second resin 207. The same resin was used for first resin 203 and second resin 209, an epoxy resin (Ablestik Product No. 2017M) being used in the present embodiment. There is no limitation with respect to this or these resin(s), provided only that it or they is or are consistent with the intent of the present invention.

In the structure of the present embodiment, first resin 203 is arranged beneath chip adhesive 206. Chip adhesive 206 contains filler in an amount that is 70 wt % thereof, and thermal expansion and contraction thereof is less than that of first resin 203. Accordingly, chip adhesive 206 does not contribute to the resin stresses acting on LED chip 204, and first resin 203 relaxes stresses acting on LED chip 204 from second resin 209.

While the shape of cavity 205 in the present embodiment is such as to constitute a cylindrical platform, such shape is not limited thereto but may be any shape permitting uniform relaxation of stresses from resin(s) that act on the LED chip 204 which is placed thereover. That is, it being sufficient that there be symmetry with respect to the center of the principal plane of the LED chip 204 which is placed thereover, such shape may, for example, be that of a truncated cone or may be hemispheric.

The depth of cavity 205 correspond to the thickness of first resin 203. As this first resin 203 relaxes stresses from second resin 209 that act on LED chip 204, it will be sufficient if the thickness thereof is not less than 20μ, but there is no particular limitation with respect thereto. While somewhat on the large side due to limitations associated with machining accuracy of lead frame 201, the thickness is 100μ in the present embodiment.

In the present embodiment, LED chip 204 is made to adhere to the insulating substrate by way of chip adhesive having thermal conductivity of not less than 2.5 W/m/K. Employed as such chip adhesive 206 was a mixture containing epoxy resin as base resin and Ag paste (e.g., Chemist CT220HK manufactured by Toshiba Chemical or T3007S manufactured by Sumitomo Metal Mining) employing Ag having thermal conductivity of not less than 170 W/m/K as filler. Because of the high thermal conductivity of the Ag paste, heat produced by LED chip 204 during supply of electricity to LED chip 204 is quickly dissipated to lead frame 201 by way of the Ag paste, permitting improvement in reliability.

Note that if the thickness of the Ag paste layer is too small, there is a possibility that breakage of the Ag paste layer could occur in the vicinity of the outer peripheral region of LED chip 204 during relaxation of stresses from the resin(s) which act on LED chip 204. It is accordingly preferred that thickness of the Ag paste layer be not less than 5μ and not more than 20μ. The upper limit of this thickness is the limiting value at which relaxation of stresses from first resin 203 can still be effectively maintained. The same applies to the embodiments described below.

The filler used in chip adhesive 206 is not limited to Ag, it being preferred for example that Au, Cu, BeO, AlN or any other substance having thermal conductivity of not less than 170 W/m/K be used as filler.

100 LED lamps prepared in accordance with the method described above were employed for each a low-temperature operation test and a high-temperature high-humidity operation test, and the change in emitted luminance over time was measured. TABLE 3 shows relative emitted luminance after 100, 500, 1,000, and 2,000 hours.

In the low-temperature operation test, relative emitted luminance after 100 hours had improved relative to the value at the start of testing, being 102% to 105% thereof, and this value was thereafter maintained in stable fashion, a relative emitted luminance of 98% to 103% being obtained at 2,000 hours.

TABLE 3

| Elapsed | | High-Temperature |
|---|---|---|
| Time | Low-Temperature | High-Humidity |
| (hours) | Operation Test | Operation Test |
| 100 | 102%-105% | 95%-98% |
| 500 | 102%-105% | 99%-102% |
| 1,000 | 102%-105% | 98%-101% |
| 2,000 | 102%-105% | 98%-103% |

Because the thickness of first resin 203 can be made larger in the present embodiment than was the case in the first embodiment, further improvement in relaxation of stresses acting on the LED chip from the resin(s) is permitted, increasing reliability.

<Third Embodiment>

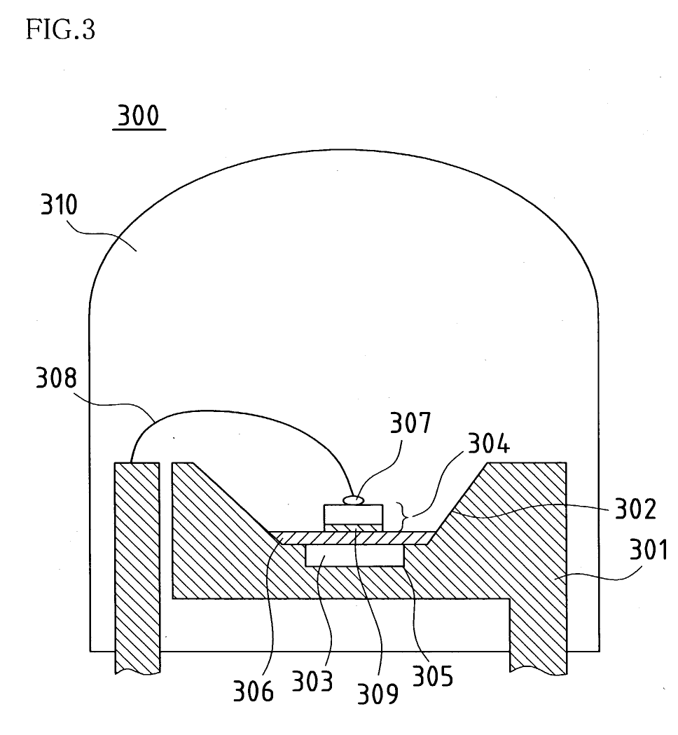

FIG. 3 is a sectional view of an LED lamp in accordance with a third embodiment of the present invention. As light emitting element, this LED lamp 300 has an LED chip 304 wherein multilayer semiconductor film containing a nitride-type compound and comprising a P—N junction is formed over n-Si substrate. Below, a procedure for assembling LED lamp 300 is described.

A dispenser is used to apply a prescribed amount of first resin 303 to cup 302 of lead frame 301 which is secured to a die bonder (not shown). Formed in the center at the bottom of cup 302 is a cavity 305 which is slightly larger than the outer periphery of LED chip 304, first resin 303 being applied so as to fill this cavity 305. The surface of this first resin 303 is made smooth, and first resin 303 is heated and cured before proceeding. In addition, chip adhesive 306, to which filler has been added, is applied to the cured first resin 303 and to the bottom of cup 302, LED chip 304 is placed over the applied chip adhesive 306, and this is heated and cured.

Thereafter, p-pad electrode 307 is formed at the principal plane of LED chip 304, and moreover, n electrode 309 is formed at the back surface of the substrate of LED chip 304. p-Pad electrode 307 is electrically connected to lead frame 301 by way of wire 308, and n electrode 309 is electrically connected to lead frame 301 by way of chip adhesive 306.

Molding is then carried out using second resin 310. The same resin was used for first resin 303 and second resin 310, a BA resin (bisphenol-A-type resin) being employed as molding resin for the light emitting diode in the present embodiment.

In the structure of the present embodiment, Ag paste was used as chip adhesive 306. As mentioned during description of the second embodiment, Ag paste permits heat to be dissipated quickly, improving reliability of the LED lamp. The Ag paste moreover provides electrical connection between LED chip 304 and lead frame 301. As substitutes for this Ag paste, it is also possible to use chip adhesives 306 wherein Cu, Au, or other such filler having high thermal conductivity and electrical conductivity is added to epoxy resin or the like.

Furthermore, it also possible to use an LED chip wherein a multilayer semiconductor film containing a nitride-type compound and comprising a PN junction is laminated over n-GaN substrate and/or over a metal thick film on the order of 100μ to 200μ.

Here also, where an LED chip is formed over such an electrically conductive substrate, an electrically conductive adhesive having thermal conductivity of not less than 2.5 W/m/K and having electrical conductivity such that the volume resistivity thereof is not more than 600 nΩm is used as chip adhesive. For example, an adhesive containing epoxy resin as base resin, to which Au, Ag, Cu, or other such electrically conductive substance having thermal conductivity of not less than 170 W/m/K and having resistivity of not more than 27 nΩm is added as filler, or the like may be used.

Whereas the same resin was used for the first resin and the second resin at the first through third embodiments, different resins may be used therefor. In such a case, it is preferred that the difference in thermal expansivity of the two resins used be on the order of 1%. Use of such resins makes it possible to cause the stresses surrounding the LED chip to be made uniform, this being a characteristic of the present invention. Note that what is here referred to as the difference in thermal expansivity is (η1-η2)/η2, where η1 and η2 are respectively the coefficients of thermal expansion of the first and second resins.

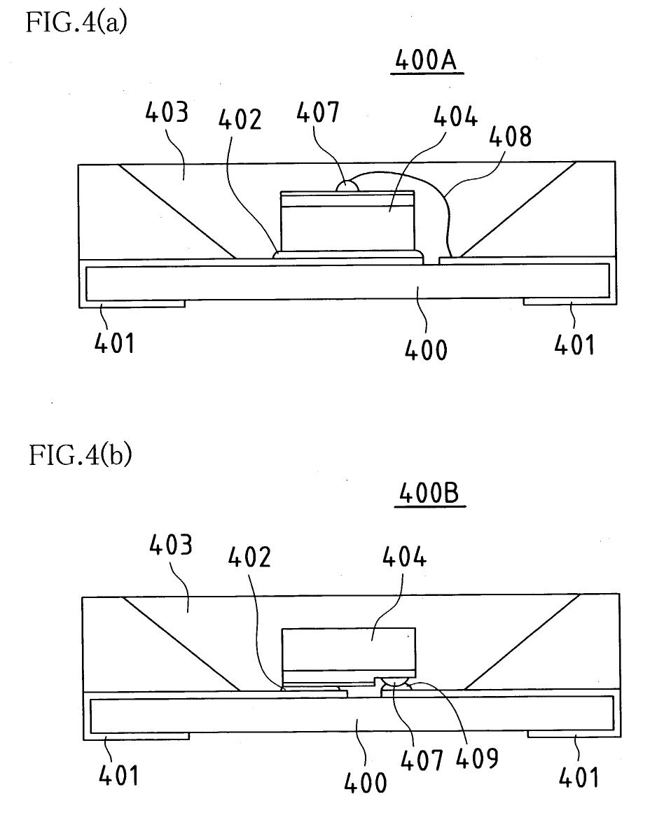

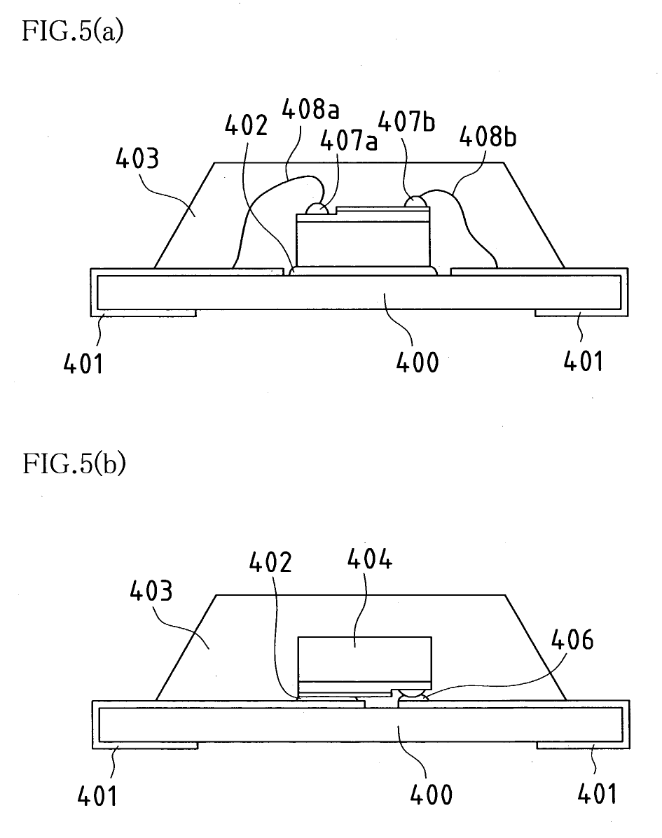

Furthermore, whereas in the first through third embodiments LED lamps having structures such that, as shown in FIGS. 1 through 3, an LED chip is placed on a lead frame and this is covered with molding resin were indicated, the present invention is not limited thereto, it also being possible, for example as shown in FIG. 4(a) and (b) or in FIG. 5(a) and (b), to form a protruding-type light emitting semiconductor device.

LED lamp 400A shown in FIG. 4(a) is such that electrically conductive film 401 is formed over insulating substrate 400, LED chip 404 being mounted over this electrically conductive film 401 by way of intervening first resin 402. Formed on this LED chip 404 is pad electrode 407, this pad electrode 407 being electrically connected to the electrically conductive film by way of wire 408. Second resin 403 is used to carry out molding around LED chip 404 having the structure described and insulating substrate 400 which contains same, forming a protruding-type LED lamp 400A in which the protruding portion is in the shape of a truncated prism.

LED lamp 400B shown in FIG. 4(b) differs in structure from LED lamp 400A in that pad electrode 407 is formed at the bottom surface of LED chip 404, electrical connection of this pad electrode 407 to electrically conductive film 401 being accomplished by way of chip adhesive 409. The structure thereof is in other respects similar to that of LED lamp 400A shown in FIG. 4(a).

In as much as they are both of the protruding type, the structure of LED lamp 500A shown in FIG. 5(a) is similar to the structure of LED lamp 400A shown in FIG. 4(a), but the former differs from the latter in that in the former the protruding portion produced by molding of second resin 403 is in the shape of a truncated cone. Furthermore, in as much as they are both of the protruding type, the structure of LED lamp 500B shown in FIG. 5(b) is likewise similar to the structure of LED lamp 400B shown in FIG. 4(b), but the former differs from the latter in that in the former the protruding portion formed by second resin 403 is in the shape of a truncated cone.

At the embodiments respectively shown in FIG. 4(a) and (b) and FIG. 5(a) and (b), resins having thermal expansivities which are on the same order are employed as first resin 402 for mounting of the LED chip and second resin 403 serving as molding resin. This makes it possible to cause the stresses surrounding the LED chip to be made uniform, permitting attainment of an LED lamp having satisfactory characteristics.

The present invention may be embodied in a wide variety of forms other than those presented herein without departing from the spirit or essential characteristics thereof. The foregoing embodiments and working examples, therefore, are in all respects merely illustrative and are not to be construed in limiting fashion. The scope of the present invention being as indicated by the claims, it is not to be constrained in any way whatsoever by the body of the specification. All modifications and changes within the range of equivalents of the claims are moreover within the scope of the present invention.

Moreover, the present application claims right of benefit of prior filing date of Japanese Patent Application No. 2002-071348, the content of which is incorporated herein by reference in its entirety. Furthermore, all references cited in the present specification are specifically incorporated herein by reference in their entirety.

What is claimed is:

1. In the context of a light emitting semiconductor device equipped with one or more LED chips in which one or more semiconductor layers comprising one or more P—N junctions are laminated over one or more substrates, and one or more support structures, on which at least one of the LED chip or chips is mounted and which provide electrical continuity to at least one of the LED chip or chips, at least one of the LED chip or chips being covered with resin, a light emitting semiconductor device characterized in that at least one of the LED chip or chips is secured by way of one or more intervening first resins to one or more mounting surfaces of at least one of the support structure or structures, and is covered by one or more second resins.

2. A light emitting semiconductor device according to claim 1 characterized in that at least one thickness of at least one of the first resin or resins is not less than 5μ and not more than 10μ.

3. In the context of a light emitting semiconductor device equipped with one or more LED chips in which one or more semiconductor layers comprising one or more P—N junctions are laminated over one or more substrates, and one or more support structures, on which at least one of the LED chip or chips is mounted and which provide electrical continuity to at least one of the LED chip or chips, at least one of the LED chip or chips being covered with resin, a light emitting semiconductor device characterized in that
at least one cavity, the perimeter at the top face of which is larger than the outer periphery of the back face of the at least one LED chip, is provided at one or more mounting surfaces of at least one of the support structure or structures; the at least one cavity is filled with one or more first resins in cured state or states; the at least one LED chip is secured over at least one of the first resin or resins by way of one or more intervening thermally conductive chip adhesives, at least one of the chip adhesive or adhesives being in physical contact with at least one of the mounting surface or surfaces; and the at least one LED chip is covered by one or more second resins.

4. A light emitting semiconductor device according to any of claims 1 through 3 characterized in that at least one of the first resin or resins and at least one of the second resin or resins are the same resin.

5. A light emitting semiconductor device according to claim 3 characterized in that the at least one chip adhesive has a thermal conductivity of not less than 2.5 W/m/K.

6. A light emitting semiconductor device according to claim 5 characterized in that the at least one chip adhesive possesses electrical conductivity such that the volume resistivity thereof is not more than 600 nΩm.
